(19) United States
(12) Patent Application Publication
(10) Pub. No.: US 2026/0260029 A1
(43) Pub. Date: Sep. 3, 2026

(54) SYSTEM AND METHOD FOR PREDICTIVE STRUCTURAL ASSET CONDITION MODELING USING HISTORICALLY CAPTURED IMAGERY, LEARNED STATE-TRANSITION FUNCTIONS, AND SEQUENTIAL ENVIRONMENTAL DATA

(71) Applicant: Kevin Kabaria, Richlands, VA (US)

(72) Inventor: Kevin Kabaria, Richlands, VA (US)

(21) Appl. No.: 19/546,426

(22) Filed: Feb. 23, 2026

Related U.S. Application Data
(60) Provisional application No. 63/762,016, filed on Feb. 23, 2025.

(51) Int. Cl. G06F 30/13

(52) U.S. Cl. CPC G06F 30/13

(57) ABSTRACT

A computer-implemented system, method, and non-transitory computer-readable medium for predicting a structural condition of a structural asset from historically captured imagery and sequential environmental data. An image encoder neural network processes at least one historically captured image of the structural asset to produce an initial condition state vector encoding visual and structural characteristics as of a capture timestamp. An environmental event sequence comprising time-ordered environmental event records spanning from the capture timestamp to a target time is retrieved. A learned state-transition function iteratively updates the condition state vector by applying the function to the condition state vector and each successive environmental event record, producing an updated condition state vector that reflects cumulative environmental effects on the structural asset. At least one condition metric indicating the predicted condition at the target time is derived from the updated condition state vector.

### CROSS-REFERENCE TO RELATED APPLICATIONS

This application claims the benefit of U.S. Provisional Application No. 63/762,016, filed Feb. 23, 2025, entitled “System and Method for Predictive Roof Condition Modeling Using Historical Imagery, Generative AI, and Environmental Data for Versatile Lead Generation and Analysis,” the entire disclosure of which is incorporated herein by reference.

### TECHNICAL FIELD

The present disclosure relates generally to computer-implemented systems and methods for structural asset condition assessment and, more specifically, to techniques for generating predicted condition representations of structural assets by combining historically captured imagery with sequential environmental event data through learned state-transition functions operating on high-dimensional latent representations.

### BACKGROUND

Structural assets such as roofs, building facades, pavements, and other exterior surfaces degrade over time due to cumulative exposure to environmental stressors including hail, wind, ultraviolet radiation, thermal cycling, precipitation, and freeze-thaw events. Because property owners rarely perform ongoing inspections, hidden degradation often persists or worsens undetected until catastrophic failure occurs.

Existing approaches to structural asset condition assessment suffer from several technical limitations. Aerial imagery providers capture current-state snapshots and extract geometric measurements such as roof pitch and area, as well as visible damage from recently acquired photographs. However, these approaches require frequent recapture of imagery to maintain accuracy and cannot estimate the condition of assets for which only older imagery is available. Storm-tracking services provide regional hail or wind maps but lack the ability to generate property-level condition assessments that account for the specific degradation trajectory of an individual asset. Insurance-centric solutions focus on risk underwriting or claims evaluation rather than producing multi-faceted condition representations that could serve diverse downstream applications.

A fundamental technical gap exists in the ability to bridge historically captured imagery of a structural asset with the intervening environmental events that have affected that asset since the imagery was captured. Without such bridging, older imagery rapidly becomes stale and provides diminishing informational value. Acquiring fresh imagery for every asset at every desired analysis time is economically and logistically prohibitive at scale. There is therefore a need for a computer-implemented system capable of ingesting one or more historically captured images of a structural asset, integrating sequential environmental event data spanning from the image capture time to a target analysis time, and producing a predicted condition representation that reflects the cumulative and interactive effects of the intervening environmental exposure without requiring new imagery capture.

Furthermore, conventional scoring approaches that assign scalar values based on aggregate exposure statistics fail to capture the order-dependent, nonlinear, and interactive nature of environmental degradation. For example, UV exposure that embrittles a roofing material followed by hail impact produces different damage than hail impact followed by UV exposure on a still-flexible material. Prior systems compute cumulative weather exposure statistics and output a scalar risk score; what is needed is a system that initializes a high-dimensional condition state from imagery, then iteratively transforms that state through a learned nonlinear transition function conditioned on each successive environmental event, producing an order-dependent final state from which diverse condition metrics, synthetic visual representations, and anomaly assessments may be derived. Such a system would provide a fundamentally more accurate and information-rich condition assessment than existing cumulative-score approaches, enabling capabilities such as counterfactual scenario analysis and construction defect detection that purely correlative systems cannot support.

### SUMMARY

In general terms, disclosed herein is a computer-implemented system and method for generating a predicted condition representation of a structural asset from historically captured imagery and sequential environmental data. The system receives one or more historically captured images of a structural asset, each associated with a capture timestamp. An image encoder neural network processes each image to produce an initial condition state vector, which is a multi-dimensional numerical representation that encodes visual and structural characteristics of the asset as of the capture time. The system retrieves an environmental event sequence comprising time-ordered environmental event records spanning from the capture timestamp to a target time. A learned state-transition function iteratively updates the condition state vector by processing each successive environmental event record, producing a final updated condition state vector that reflects the predicted condition of the structural asset at the target time. One or more condition metrics are derived from the updated condition state vector to quantify the asset's predicted state.

In some embodiments, the system further comprises a generative decoder that transforms the updated condition state vector into a synthetic image approximating the visual appearance of the structural asset at the target time. In some embodiments, a divergence verification module compares the synthetic image or the updated condition state vector against a newly acquired image of the same asset to detect anomalies such as unreported repairs, construction defects, or environmental events not captured in the event sequence. In various embodiments, the system outputs assessment records comprising condition metrics, synthetic images, confidence indicators, and provenance information suitable for integration with external systems such as contractor management platforms, property monitoring dashboards, insurance underwriting engines, or building information management systems.

The disclosed approach provides several technical improvements over conventional structural condition assessment. By modeling degradation as a sequence of discrete, event-conditioned state transitions rather than as a single aggregate score, the system captures order-dependent and interactive degradation effects that cumulative approaches cannot represent. The high-dimensional condition state vector encodes richer structural and material information than scalar scoring, enabling diverse downstream derivations from a single representation. The learned state-transition function generalizes across materials, geometries, and environmental regimes after training, enabling scalable assessment of large asset portfolios without requiring per-asset physical inspection. The optional divergence verification provides a closed-loop validation mechanism that identifies deviations from expected degradation trajectories, enabling detection of construction defects, unreported repairs, or missing environmental event data.

In some embodiments, the state-transition function supports bidirectional temporal analysis, enabling both forward prediction of future condition and reverse-temporal forensic analysis of past condition from current observations. In some embodiments, the system supports counterfactual analysis by modifying environmental event sequences or material parameters to simulate hypothetical degradation scenarios. These capabilities extend the utility of the condition representation beyond simple assessment to encompass scenario modeling, intervention planning, and root-cause investigation.

### BRIEF DESCRIPTION OF THE DRAWINGS

FIG. 1 is a block diagram illustrating an overall system architecture for predictive structural asset condition modeling in accordance with one or more embodiments.

FIG. 2 is a block diagram illustrating a data input pipeline and image preprocessing module in accordance with one or more embodiments.

FIG. 3 is a flowchart illustrating a method for sequential state-vector updating using a learned state-transition function in accordance with one or more embodiments.

FIG. 4 is a flowchart illustrating a single-property inference flow from address input to condition output in accordance with one or more embodiments.

FIG. 5 is a data-flow diagram illustrating an environmental event record schema and temporal alignment in accordance with one or more embodiments.

FIG. 6 is a block diagram illustrating a generative decoding pipeline for producing synthetic images from a condition state vector in accordance with one or more embodiments.

FIG. 7 is a flowchart illustrating a divergence verification process comparing predicted and observed imagery in accordance with one or more embodiments.

FIG. 8 is a flowchart illustrating a training pipeline for the image encoder, state-transition function, and generative decoder in accordance with one or more embodiments.

FIG. 9 is a block diagram illustrating a batch processing architecture for portfolio-scale condition assessment in accordance with one or more embodiments.

FIG. 10 is a flowchart illustrating a feedback and retraining loop incorporating field verification data in accordance with one or more embodiments.

FIG. 11 is a state diagram illustrating a machine learning model lifecycle including training, evaluation, deployment, monitoring, and retraining stages in accordance with one or more embodiments.

FIG. 12 is a block diagram illustrating a multi-asset extension architecture supporting diverse structural asset types in accordance with one or more embodiments.

FIG. 13 is a block diagram illustrating deployment architecture variants including cloud, on-premises, edge, and hybrid configurations in accordance with one or more embodiments.

FIG. 14 is a data-flow diagram illustrating an assessment record structure and provenance chain in accordance with one or more embodiments.

### DETAILED DESCRIPTION

### Definitions and Terminology

As used herein, the following terms have the indicated meanings unless the context clearly dictates otherwise.

“Structural asset” refers to any physical structure or component thereof whose condition changes over time due to environmental exposure. Non-limiting examples include residential roofs, commercial roofs, building facades, curtain walls, pavements, bridge decks, siding, gutters, pool enclosures, and other exterior structural surfaces. Unless otherwise specified, the term encompasses both the structure as a whole and identifiable sub-regions or components thereof.

“Historically captured image” (also referred to as a “stale image”) refers to one or more digital images of a structural asset that were captured at a prior time and that may no longer reflect the asset's current condition due to intervening environmental exposure. Historically captured images may be aerial photographs, satellite images, drone imagery, ground-level photographs, or any combination thereof, and may vary in resolution, spectral content, angle of capture, and quality.

“Capture timestamp” refers to a date, date-time, or temporal identifier associated with a historically captured image that indicates when the image was acquired. The capture timestamp need not be precise to the second; in some embodiments, a date or month-year approximation suffices.

“Condition state vector” (also referred to as a “roof-state vector” when the structural asset is a roof) refers to a multi-dimensional numerical representation that encodes the predicted condition of a structural asset at a particular point in time. The condition state vector resides in a high-dimensional latent space and may encode information relating to material integrity, surface degradation, moisture exposure, structural stress, color or texture changes, or any other condition-relevant attributes. In some embodiments, the condition state vector comprises between 10 and 1024 dimensions, though dimensionalities outside this range are equally contemplated. The condition state vector resides in a learned latent space produced by training the image encoder and the state-transition function on condition-relevant data, such that the latent space organizes condition representations according to structural and material similarity.

“Environmental event sequence” refers to a time-ordered collection of environmental event records spanning a defined temporal interval. Each record in the sequence characterizes one or more environmental conditions during a corresponding time period. The sequence preserves temporal ordering such that earlier events precede later events.

“Environmental event record” refers to a structured data element describing environmental conditions for a defined time interval at or near the location of a structural asset. In some embodiments, an environmental event record comprises one or more of: hail occurrence and hail diameter, wind speed and direction, precipitation type and amount, temperature and temperature range, ultraviolet radiation index, freeze-thaw cycle count, humidity, and barometric pressure. The temporal granularity of event records may range from sub-hourly to monthly or longer intervals.

“Event feature vector” refers to a numerical representation derived from one or more environmental event records, suitable for input to the state-transition function. In some embodiments, the event feature vector is produced by a dedicated encoder that maps raw event record fields to a fixed-dimensional numerical space.

“State-transition function” refers to a learned computational function that accepts a current condition state vector and an event feature vector as inputs and produces an updated condition state vector as output. The state-transition function models the effect of the environmental conditions described by the event feature vector on the structural asset whose condition is represented by the input state vector. In various embodiments, the state-transition function is implemented as a recurrent neural network, a transformer-based neural network, a graph neural network, a neural ordinary differential equation, or any combination thereof.

“State update delta” refers to the difference between a condition state vector before and after a single application of the state-transition function. In some embodiments, the state-transition function explicitly computes a state update delta and applies it additively to the input condition state vector to produce the output condition state vector. The state update delta captures the magnitude and direction of condition change attributable to a particular environmental event or time interval.

“Condition metric” refers to a scalar value, vector, classification label, probability distribution, or structured data element derived from a condition state vector that quantifies one or more aspects of a structural asset's predicted condition. Non-limiting examples of condition metrics include: a remaining useful life estimate, a damage severity score, a material degradation index, a maintenance urgency indicator, an actionable-priority index, a multi-attribute condition profile, and a probability distribution over discrete condition categories.

“Generative decoder” refers to a neural network or computational module that transforms a condition state vector into a synthetic image or other perceptual representation of the structural asset at the condition described by the state vector. In various embodiments, the generative decoder is implemented as a diffusion model, a generative adversarial network, a variational autoencoder decoder, or any combination thereof.

“Divergence verification” refers to a process of comparing a predicted condition representation (such as a synthetic image or condition state vector) against an independently obtained observation (such as a newly captured image) of the same structural asset. Divergence verification produces a divergence measure indicating the degree of discrepancy between the prediction and the observation.

“Assessment record” refers to a structured data object comprising at least one condition metric, the identity of the assessed structural asset, and temporal context indicating the target time of the assessment. In some embodiments, an assessment record further comprises one or more of: a confidence indicator, a synthetic image, a divergence measure, provenance metadata identifying the input data and model version used, and an audit trail.

“Calibration baseline” refers to an expected degradation trajectory for a structural asset under known or modeled environmental conditions. In some embodiments, the calibration baseline is computed by running the state-transition function forward from a known initial state using modeled or historical environmental data. Deviations from the calibration baseline may indicate construction defects, unreported repairs, anomalous environmental events, or model error.

“Contextual metadata” refers to supplementary information about a structural asset or its environment that is not derived from imagery or environmental event data but that may influence condition prediction. Non-limiting examples include: material type, installation date, roof pitch, geographic region, nearby vegetation, building use type, and regional roofing composition statistics.

### System Architecture

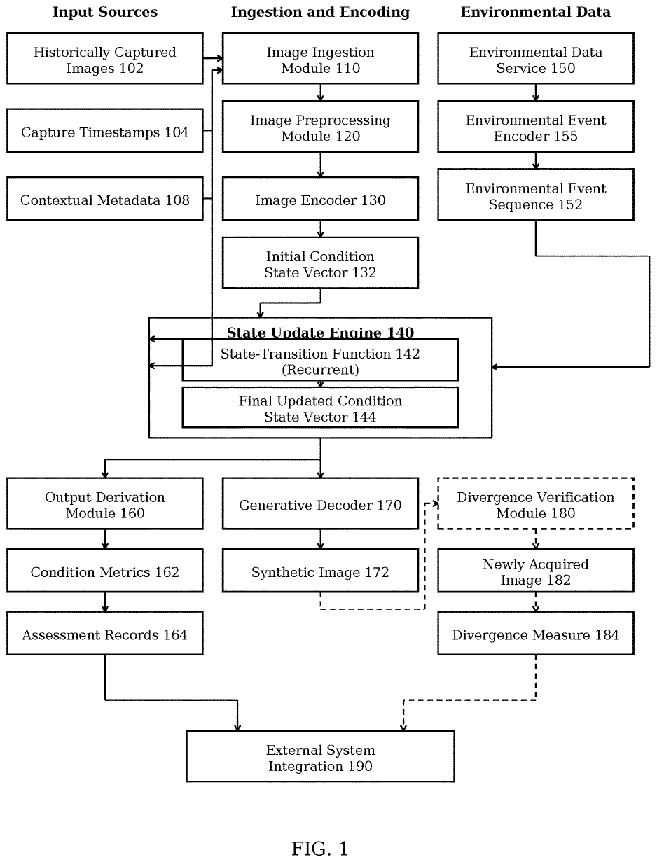

Referring now to FIG. 1, an overall system architecture 100 for predictive structural asset condition modeling is illustrated in accordance with one or more embodiments. The system 100 comprises an image ingestion module 110, an image preprocessing module 120, an image encoder 130, a state update engine 140, an environmental data service 150, an output derivation module 160, and an optional generative decoder 170.

The image ingestion module 110 receives one or more historically captured images 102 of a structural asset, together with associated capture timestamps 104 and, optionally, property identifiers 106 such as addresses or geographic coordinates. The historically captured images 102 may originate from aerial imagery providers, satellite imagery archives, drone surveys, property inspection databases, or user uploads. In some embodiments, the image ingestion module 110 retrieves imagery from an image database 112 that indexes images by property identifier and capture date.

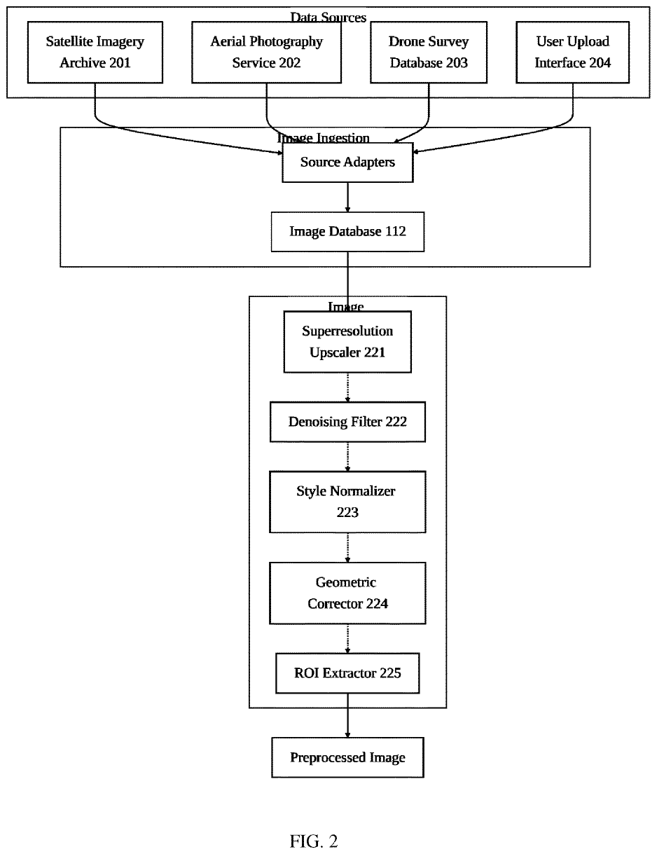

The image preprocessing module 120 performs one or more preprocessing operations on each historically captured image to improve its suitability for encoding. As illustrated in greater detail in FIG. 2, preprocessing operations may include super resolution upscaling to enhance low-resolution satellite or aerial imagery, denoising to remove compression artifacts or sensor noise, style normalization to reduce variability due to lighting conditions, atmospheric haze, or camera characteristics, geometric correction to account for varying capture angles, and region-of-interest extraction to isolate the structural asset from surrounding context. In some embodiments, a roof boundary detection sub-module identifies the footprint of the structural asset within a larger scene image and crops the image accordingly.

The image encoder 130 processes each preprocessed image to produce an initial condition state vector 132. In various embodiments, the image encoder 130 comprises a convolutional neural network, a vision transformer, a hybrid convolutional-transformer architecture, or a pre-trained foundation model fine-tuned for structural condition encoding. The image encoder 130 maps the input image to a point in a high-dimensional latent space such that images of similar structural conditions map to nearby points and images of dissimilar conditions map to distant points. In some embodiments, the image encoder 130 is trained jointly with the state-transition function 142 and the generative decoder 170 in an end-to-end training pipeline. In some embodiments, the image encoder 130 produces a spatially resolved condition tensor comprising condition state sub-vectors for each of a grid of spatial regions within the structural asset, enabling localized condition assessment.

The environmental data service 150 retrieves, aggregates, and formats environmental event data for the geographic location and temporal interval of interest. In some embodiments, the environmental data service 150 queries one or more external data providers including national weather services, commercial weather data vendors, radar-derived precipitation databases, hail report databases, ultraviolet index services, and temperature archives. In some embodiments, the environmental data service 150 retrieves weather data on a per-property basis using the geographic coordinates of the structural asset to select the most relevant weather station or grid point. The environmental data service 150 produces an environmental event sequence 152 comprising time-ordered environmental event records spanning from the capture timestamp of the historically captured image to a target analysis time.

In some embodiments, the environmental data service 150 further comprises an environmental event encoder 155 that transforms raw environmental event records into event feature vectors suitable for consumption by the state-transition function 142. Raw environmental data fields, which may comprise heterogeneous data types including numerical values, categorical labels, and boolean indicators, are projected into a fixed-dimensional numerical representation through the environmental event encoder 155. In some embodiments, the environmental event encoder 155 comprises a feedforward neural network that maps concatenated and normalized raw fields to a dense vector in the same dimensional space as the condition state vector, enabling direct interaction between the environmental representation and the condition representation within the state-transition function. In some embodiments, the environmental event encoder 155 applies normalization to numerical fields, one-hot encoding to categorical fields, and learned embeddings to high-cardinality categorical fields before producing the event feature vector. The environmental event encoder 155 ensures that environmental data from diverse sources and formats is consistently represented in a form that the state-transition function can process.

The state update engine 140 implements the core sequential condition-update pipeline. The state update engine 140 comprises a state-transition function 142, which is a trained neural network that accepts a current condition state vector and an event feature vector and produces an updated condition state vector. The state update engine 140 iterates over the environmental event sequence 152, applying the state-transition function 142 at each time step to produce a progressively updated condition state vector. After processing all event records in the sequence, the state update engine 140 outputs a final updated condition state vector 144 representing the predicted condition of the structural asset at the target time.

In some embodiments, the state-transition function 142 is implemented as a recurrent neural network such as a long short-term memory (LSTM) network or a gated recurrent unit (GRU) network, where the hidden state corresponds to the condition state vector. In some embodiments, the state-transition function 142 is implemented as a transformer-based architecture that processes the environmental event sequence using self-attention mechanisms. In some embodiments, the state-transition function 142 is implemented as a graph neural network that models the structural asset as a graph of interconnected components, with message-passing operations propagating condition updates between adjacent components. In some embodiments, the state-transition function 142 is implemented as a neural ordinary differential equation that models continuous-time state evolution. In some embodiments, multiple state-transition function architectures are available and the system selects among them based on asset type, data availability, or computational constraints.

In some embodiments, the state-transition function 142 computes an explicit state update delta at each iteration, which is additively applied to the current condition state vector to produce the updated condition state vector. This delta-based formulation enables the system to track the magnitude and direction of condition change attributable to each environmental event or time interval. In some embodiments, the cumulative sum of state update deltas over an interval provides a summary of total condition change that can be decomposed by contributing environmental factor.

In some embodiments, the state-transition function 142 is conditioned on contextual metadata 108 such as material type, roof pitch, geographic region, installation date, or nearby vegetation. The contextual metadata 108 may be provided as an additional input vector concatenated with or otherwise combined with the event feature vector at each time step, or may be provided as a one-time conditioning signal that modulates the parameters or behavior of the state-transition function 142.

Because the state-transition function 142 processes environmental events sequentially and the condition state vector retains a complete representation of the asset's accumulated degradation history at each step, the system inherently models cross-stressor interaction effects. The effect of a given environmental stressor on the condition state vector depends on the current state, which reflects the cumulative and ordered history of all prior stressors. For example, prolonged ultraviolet exposure may increase the brittleness dimensions of the condition state vector, such that a subsequent hail event produces a larger state update delta in damage-related dimensions than the same hail event would produce on a condition state vector that had not accumulated prior UV exposure. This sequential conditioning enables the system to capture nonlinear, order-dependent degradation phenomena that additive or cumulative exposure scoring approaches cannot represent, because additive approaches compute a final score from aggregate exposure statistics without maintaining an evolving state that mediates inter-stressor dependencies.

The causal structure of the state-transition function 142 distinguishes the disclosed system from correlative approaches. Rather than mapping aggregate environmental statistics to a condition score through learned correlations, the state-transition function 142 explicitly models how each environmental event transforms the condition state, conditioned on the full prior state history. This causal conditioning during training enables the system to predict condition outcomes for environmental event sequences not present in the training data, including novel combinations of stressor types, intensities, and orderings. The causal structure further enables counterfactual analysis, in which modified environmental event sequences are processed through the same state-transition function to predict hypothetical condition trajectories, a capability that is not achievable through purely correlative scoring because correlative models do not maintain the state information necessary to evaluate the effect of changing individual events within a sequence.

The learned state-transition function of the disclosed system is distinguished from classical sequential estimation methods such as Kalman filters and hidden Markov models (HMMs). Kalman filters assume linear state dynamics and Gaussian-distributed process and observation noise, restricting them to low-dimensional state representations where analytic update equations are tractable. Hidden Markov models assume a finite, discrete state space with memoryless (Markov) transitions between a limited number of categorical states, which cannot represent the continuous, high-dimensional condition information encoded in the condition state vector. By contrast, the state-transition function of the disclosed system is a learned nonlinear neural network operating in a continuous high-dimensional latent space, making no assumptions about the functional form of state transitions, the distribution of observation noise, or the cardinality of the state space. This learned nonlinear formulation enables the system to capture complex, multi-factor degradation dynamics including cross-stressor interactions and order-dependent effects that linear or discrete-state sequential models cannot represent. The neural network-based approach further enables end-to-end training from data, allowing the transition dynamics to be learned jointly with the image encoder and output derivation modules rather than requiring manual specification of state equations or transition probability matrices.

The output derivation module 160 derives one or more condition metrics 162 from the final updated condition state vector 144. In various embodiments, the output derivation module 160 comprises one or more of: a linear or nonlinear projection layer that maps the condition state vector to a scalar condition score, a multi-head output network that produces a multi-attribute condition profile comprising damage severity, material degradation, remaining useful life, and maintenance urgency components, a classification head that assigns the structural asset to a discrete condition category, and a confidence estimation module that produces uncertainty bounds or a probability distribution over condition outcomes.

The optional generative decoder 170 transforms the final updated condition state vector 144 into a synthetic image 172 that approximates the visual appearance of the structural asset at the predicted condition. In various embodiments, the generative decoder 170 is implemented as a diffusion model, a conditional generative adversarial network, or a decoder portion of a variational autoencoder. The synthetic image 172 may be used for visual communication to property owners, for divergence verification against newly acquired imagery, or for quality assurance of the condition prediction.

In some embodiments, the system 100 further comprises a divergence verification module 180 that compares the synthetic image 172 or the final updated condition state vector 144 against a newly acquired image 182 of the same structural asset. The divergence verification module 180 computes a divergence measure 184 indicating the degree of discrepancy between the predicted and observed conditions. In some embodiments, the divergence measure 184 is computed using one or more of: pixel-level image similarity metrics, perceptual similarity metrics such as learned perceptual image patch similarity, embedding-space distance metrics such as cosine similarity or Euclidean distance between condition state vectors, and structural similarity indices.

In some embodiments, responsive to the divergence measure 184 exceeding a configurable threshold, the system 100 automatically performs one or more of: flagging the structural asset for manual review, generating an anomaly assessment record indicating suspected unreported repair, construction defect, or environmental event not captured in the event sequence, triggering re-analysis with an expanded environmental data search, or scheduling a physical inspection.

### Detailed Textual Descriptions of Figures

### FIG. 1—Overall System Architecture

FIG. 1 depicts a block diagram of the overall system architecture 100. At the top left, historically captured images 102 and associated capture timestamps 104 enter the image ingestion module 110. An arrow leads from module 110 to the image preprocessing module 120, which outputs preprocessed images to the image encoder 130. The image encoder 130 outputs an initial condition state vector 132.

In the center of FIG. 1, the environmental data service 150 is shown receiving a property location and temporal range and outputting an environmental event sequence 152 comprising a vertical stack of time-ordered event records. An environmental event encoder 155 within the environmental data service 150 transforms each raw environmental event record into an event feature vector suitable for consumption by the state-transition function 142. The state update engine 140 occupies the central position and receives the initial condition state vector 132 from the image encoder 130, event feature vectors from the environmental event encoder 155, and the capture timestamp 104 from the image ingestion module 110. The capture timestamp 104 is provided to the state update engine 140 so that the state update engine 140 can temporally align the initial condition state vector 132 with the environmental event sequence 152 and order subsequent state updates with respect to the time of image capture. Contextual metadata 108 enters the state update engine 140 as an additional input. The state update engine 140 contains the state-transition function 142, shown as a repeating block with a recurrence arrow indicating iterative application. The output of the state update engine 140 is the final updated condition state vector 144.

At the right side of FIG. 1, the final updated condition state vector 144 feeds into multiple optional output branches. The output derivation module 160 produces condition metrics 162 and assessment records 164. The optional generative decoder 170 produces a synthetic image 172. Each output branch is independently optional; the system may produce condition metrics only, condition metrics and a synthetic image, or any other combination of outputs as required by the deployment configuration. A dashed box labeled divergence verification module 180 receives the synthetic image 172 and a newly acquired image 182, producing a divergence measure 184. The divergence verification module 180 is likewise optional and operates only when both a predicted condition representation and a newly acquired image are available. External system integration points 190 are shown receiving outputs from both the output derivation module 160 and the divergence verification module 180.

### FIG. 2—Data Input Pipeline and Preprocessing

FIG. 2 depicts a detailed view of the image ingestion module 110 and the image preprocessing module 120. Raw images from diverse sources (satellite imagery archive 201, aerial photography service 202, drone survey database 203, user upload interface 204) flow into the image ingestion module 110 through respective adapters. The image ingestion module 110 associates each image with a capture timestamp and property identifier and stores indexed records in the image database 112.

From the image database 112, images pass through a sequence of preprocessing stages within module 120: a super resolution upscaler 221, a denoising filter 222, a style normalizer 223, a geometric corrector 224, and a region-of-interest extractor 225. Each stage is shown as optional (dashed border), indicating that the preprocessing pipeline is configurable per deployment. The output of module 120 is a preprocessed image ready for encoding.

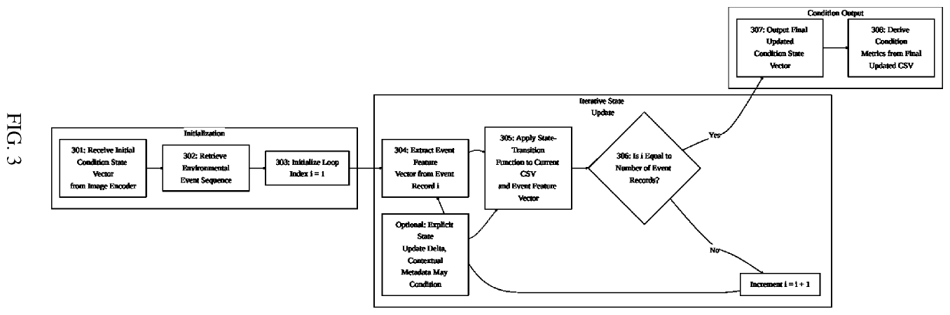

### FIG. 3—Sequential State-Vector Updating

FIG. 3 depicts a flowchart of the sequential state-update method. The flow begins at step 301 (Receive initial condition state vector from image encoder). Step 302 (Retrieve environmental event sequence for the temporal interval). Step 303 (Initialize loop index i=1). Step 304 (Extract event feature vector from event record i). Step 305 (Apply state-transition function to current condition state vector and event feature vector to produce updated condition state vector). Step 306 (Decision: Is i equal to the number of event records? If no, increment i and return to step 304. If yes, proceed to step 307). Step 307 (Output final updated condition state vector). Step 308 (Derive condition metrics from final updated condition state vector).

An annotation alongside step 305 indicates that the state-transition function may optionally compute an explicit state update delta that is additively applied to the condition state vector, and that contextual metadata may condition the function at each step.

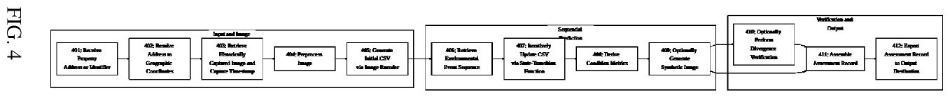

### FIG. 4—Single-Property Inference Flow

FIG. 4 depicts a flowchart for a single-property inference workflow. Step 401 (Receive property address or identifier from user or batch queue). Step 402 (Resolve address to geographic coordinates). Step 403 (Retrieve historically captured image and capture timestamp from image database). Step 404 (Preprocess image). Step 405 (Generate initial condition state vector via image encoder). Step 406 (Retrieve environmental event sequence from capture timestamp to target time). Step 407 (Iteratively update condition state vector via state-transition function). Step 408 (Derive condition metrics). Step 409 (Optionally generate synthetic image via generative decoder). Step 410 (Optionally perform divergence verification if newly acquired image is available). Step 411 (Assemble assessment record with metrics, optional synthetic image, confidence, and provenance). Step 412 (Export assessment record to output destination: API response, report, CRM integration, dashboard, or file export).

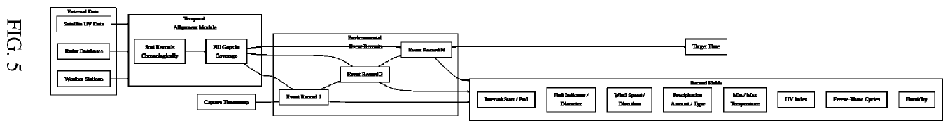

### FIG. 5—Environmental Event Record Schema

FIG. 5 depicts a data-flow diagram showing the structure of environmental event records and their temporal alignment. A timeline runs horizontally across the center, marked with the capture timestamp at the left end and the target time at the right end. Between these endpoints, vertical tick marks indicate the boundaries of successive time intervals. Each interval is associated with an environmental event record shown as a structured data element containing fields including: interval start time, interval end time, hail indicator and hail diameter, maximum wind speed and prevailing wind direction, total precipitation amount and precipitation type, minimum and maximum temperature, UV index, freeze-thaw cycle count, and humidity. Arrows from external data sources (weather stations, radar databases, satellite UV measurements) feed into the event records. A temporal alignment module ensures that event records are sorted in chronological order and that gaps are filled with default or interpolated values.

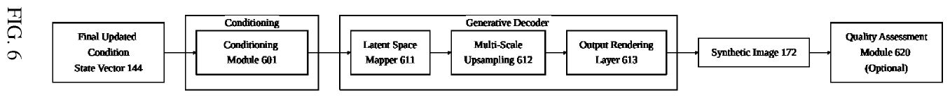

### FIG. 6—Generative Decoding Pipeline

FIG. 6 depicts a block diagram of the generative decoding pipeline. The final updated condition state vector 144 enters a conditioning module 601 that formats the vector as input conditioning for the generative decoder 170. The generative decoder 170 is shown with an internal architecture comprising a latent space mapper 611, a multi-scale upsampling network 612, and an output rendering layer 613. The output is a synthetic image 172 of the structural asset at the predicted condition. An optional quality assessment module 620 evaluates the synthetic image for visual plausibility and flags low-confidence generations.

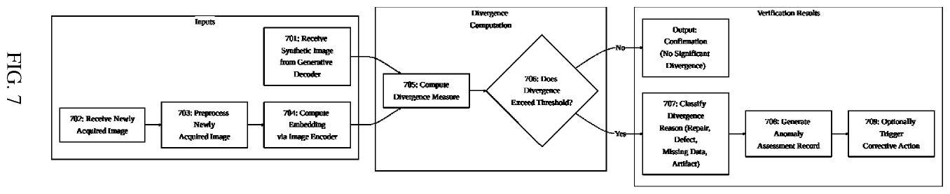

### FIG. 7—Divergence Verification Process

FIG. 7 depicts a flowchart of the divergence verification process. Step 701 (Receive synthetic image from generative decoder). Step 702 (Receive newly acquired image of the same structural asset). Step 703 (Preprocess newly acquired image using the same preprocessing pipeline). Step 704 (Compute embedding of newly acquired image using the image encoder). Step 705 (Compute divergence measure using one or more metrics: embedding-space distance, pixel-level similarity, perceptual similarity). Step 706 (Decision: Does divergence exceed threshold? If no, output confirmation that predicted condition is consistent with observation. If yes, proceed to step 707). Step 707 (Classify divergence reason: suspected repair or replacement, suspected construction defect, suspected missing environmental event data, suspected image artifact or capture-condition difference). Step 708 (Generate anomaly assessment record with divergence details and classification). Step 709 (Optionally trigger corrective action: schedule inspection, flag for manual review, expand environmental data search, re-run prediction with adjusted parameters).

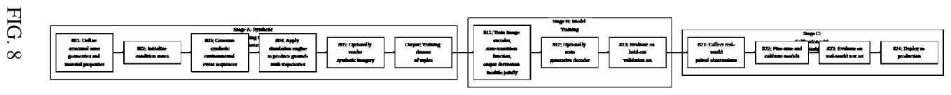

### FIG. 8—Training Pipeline

FIG. 8 depicts a flowchart of the training pipeline for the system's neural network components. The training pipeline comprises three stages. Stage A (Synthetic Training Data Generation): Step 801 (Define structural asset geometries and material properties using a construction grammar comprising a library of parameterized structural primitives). Step 802 (Initialize condition states for each synthetic asset). Step 803 (Generate synthetic environmental event sequences spanning multi-year time horizons). Step 804 (Apply a simulation engine to each synthetic asset and its event sequence to produce ground-truth condition state trajectories). Step 805 (Optionally render synthetic imagery for each condition state using a visual rendering module). The output of Stage A is a training dataset comprising tuples of (initial image or condition state, environmental event sequence, ground-truth final condition state, optional ground-truth visual).

Stage B (Model Training): Step 811 (Train image encoder, state-transition function, and output derivation module jointly on the training dataset, minimizing a loss function that penalizes discrepancy between predicted and ground-truth final condition states). Step 812 (Optionally train generative decoder to reconstruct visual representations from condition state vectors, using adversarial or perceptual loss functions). Step 813 (Evaluate trained models on a held-out validation set using metrics including mean absolute error on condition metrics, condition-category classification accuracy, and visual quality metrics for synthetic images).

Stage C (Calibration with Real-World Data): Step 821 (Collect real-world paired observations comprising historically captured images with known capture timestamps, environmental event sequences for the intervening period, and independently obtained condition assessments or recent imagery). Step 822 (Fine-tune or calibrate the trained models on real-world data). Step 823 (Evaluate calibrated models on a real-world test set). Step 824 (Deploy calibrated models to production inference environment).

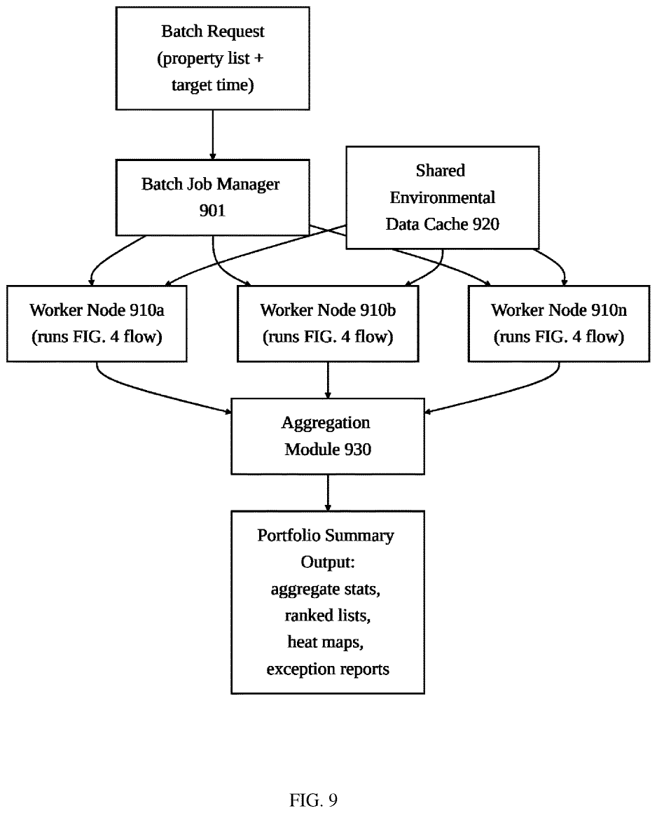

### FIG. 9—Batch Processing Architecture

FIG. 9 depicts a block diagram of a batch processing architecture for portfolio-scale condition assessment. A batch job manager 901 receives a batch request comprising a list of property identifiers and a target analysis time. The batch job manager 901 distributes individual assessment tasks across a pool of worker nodes 910a, 910b, through 910n, each executing the single-property inference flow of FIG. 4. A shared environmental data cache 920 stores recently retrieved environmental event sequences to avoid redundant data retrieval for properties in geographic proximity. An aggregation module 930 collects assessment records from all workers and produces a portfolio-level summary comprising aggregate statistics, ranked property lists, geographic heat maps, and exception reports for properties with high divergence or low confidence.

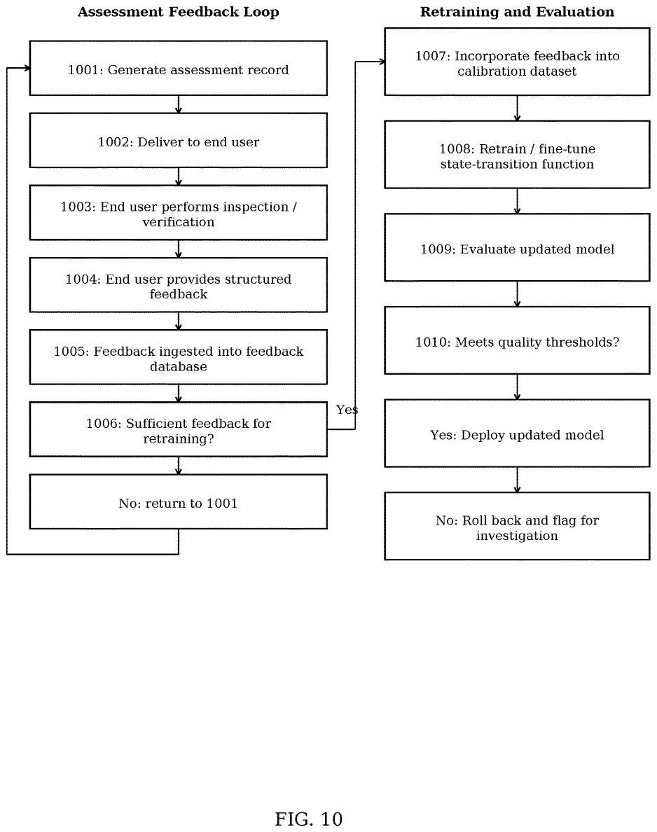

### FIG. 10—Feedback and Retraining Loop

FIG. 10 depicts a flowchart of the feedback and retraining loop. Step 1001 (System generates assessment record for a structural asset). Step 1002 (Assessment record is delivered to an end user such as a contractor, property manager, or inspector). Step 1003 (End user performs a physical inspection or obtains independent verification of the asset's condition). Step 1004 (End user provides structured feedback indicating whether the predicted condition was accurate, partially accurate, or inaccurate, and optionally provides observed condition details). Step 1005 (Feedback data is ingested into a feedback database). Step 1006 (Decision: Has sufficient new feedback accumulated to trigger a retraining cycle? If no, return to step 1001 for next assessment. If yes, proceed to step 1007). Step 1007 (Incorporate feedback data into calibration dataset). Step 1008 (Retrain or fine-tune state-transition function and output derivation module). Step 1009 (Evaluate updated model against held-out test set). Step 1010 (Decision: Does updated model meet quality thresholds? If yes, deploy updated model. If no, roll back to previous model version and flag for manual investigation).

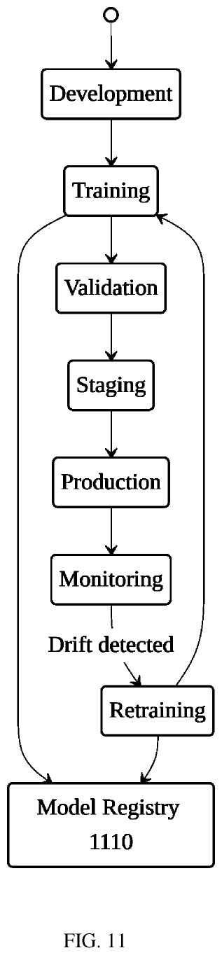

### FIG. 11—ML Model Lifecycle

FIG. 11 depicts a state diagram of the machine learning model lifecycle. States include: Development (initial architecture selection and hyperparameter exploration), Training (execution of the training pipeline of FIG. 8), Validation (evaluation against held-out test sets and quality gates), Staging (deployment to a pre-production environment for integration testing), Production (active service of inference requests), Monitoring (continuous evaluation of model performance against incoming feedback and drift indicators), and Retraining (triggered when monitoring detects performance degradation exceeding a threshold). Transitions between states are labeled with the conditions or events that trigger them. A Model Registry 1110 is shown as a persistent store that versions all model artifacts and supports rollback to any previous version.

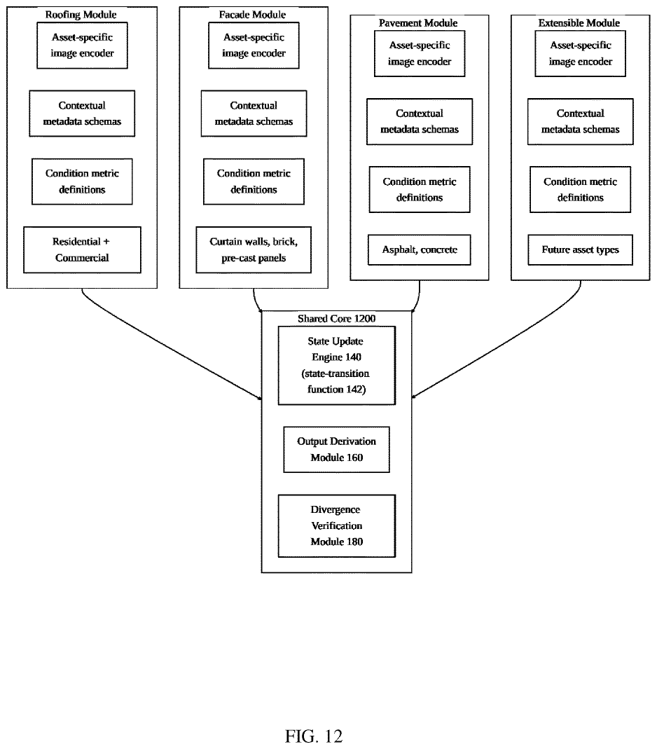

### FIG. 12—Multi-Asset Extension Architecture

FIG. 12 depicts a block diagram showing how the system architecture extends to diverse structural asset types. A shared core 1200 comprises the state update engine 140, the output derivation module 160, and the divergence verification module 180. Asset-specific modules are shown as plug-in components: a roofing module 1210 (residential and commercial roof types), a facade module 1220 (curtain walls, brick veneers, pre-cast panels), a pavement module 1230 (asphalt, concrete), and an extensible placeholder module 1240 for future asset types. Each asset-specific module provides an asset-specific image encoder, asset-specific contextual metadata schemas, and asset-specific condition metric definitions. The state-transition function 142 within the shared core may be a single cross-domain model trained on diverse asset types or a collection of asset-specific models selected by an asset type classifier.

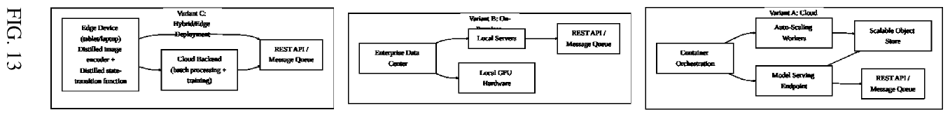

### FIG. 13—Deployment Architecture Variants

FIG. 13 depicts a block diagram of three deployment architecture variants. Variant A (Cloud Deployment): All system components execute on cloud infrastructure including a managed container orchestration platform, a model serving endpoint, a scalable object store for imagery, and auto-scaling worker pools. Variant B (On-Premises Deployment): All system components execute within an enterprise data center, with imagery and environmental data stored on local servers and inference performed on local GPU-equipped hardware. Variant C (Hybrid/Edge Deployment): A lightweight inference client executes on an edge device such as a tablet or laptop with compressed or distilled versions of the image encoder and the state-transition function, performing single-property assessments locally, while batch processing and model training remain on cloud infrastructure. In all variants, a REST API or message queue interface provides integration with external systems.

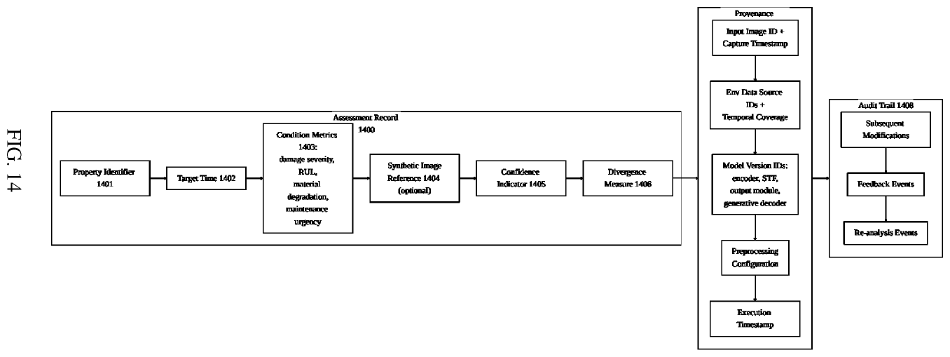

### FIG. 14—Assessment Record and Provenance Chain

FIG. 14 depicts a data-flow diagram of the assessment record structure and its provenance chain. An assessment record 1400 is shown as a structured object comprising: property identifier 1401, target time 1402, condition metrics 1403 (which may include damage severity, remaining useful life, material degradation index, and maintenance urgency), optional synthetic image reference 1404, confidence indicator 1405, divergence measure 1406 (if divergence verification was performed), and provenance metadata 1407. The provenance metadata 1407 comprises: input image identifier and capture timestamp, environmental data source identifiers and temporal coverage, model version identifiers for the image encoder, state-transition function, output derivation module, and generative decoder, preprocessing configuration, and execution timestamp. An audit trail 1408 records any subsequent modifications to the assessment record including feedback incorporation and re-analysis events.

### Data Lifecycle and Schema

The system processes data through a defined lifecycle comprising ingestion, preprocessing, encoding, sequential updating, output derivation, and optional verification and feedback stages.

During ingestion, historically captured images are received from one or more sources and associated with property identifiers, capture timestamps, and optional contextual metadata. In some embodiments, the system maintains an image database indexed by property identifier and capture date, enabling retrieval of the most relevant image for a given assessment request. When multiple images are available for the same property at different times, the system may select the image closest to the target time, use the oldest image to maximize the temporal span of the prediction, or initialize multiple condition state vectors from multiple images and reconcile them.

Environmental event records conform to a schema comprising at minimum a time interval identifier and one or more environmental condition fields. In some embodiments, the schema includes the following fields: interval_start (timestamp), interval_end (timestamp), hail_indicator (boolean), hail_max_diameter_mm (float, 0-150), wind_speed_max_kph (float, 0-400), wind_direction_degrees (integer, 0-359), precipitation_total_mm (float, 0-500), precipitation_type (categorical: none, rain, snow, sleet, mixed), temperature_min_celsius (float, −60 to 60), temperature_max_celsius (float, −60 to 60), uv_index_max (float, 0-15), freeze_thaw_cycles (integer, 0-10), and relative_humidity_percent (float, 0-100). These ranges are non-limiting examples.

In some embodiments, environmental event records further comprise geographic specificity indicators such as the distance from the reporting weather station to the structural asset and a confidence weight reflecting the spatial and temporal precision of the environmental data. In some embodiments, multiple environmental data sources are queried and their records are merged, with conflicts resolved by weighting sources according to their proximity and reliability.

In some embodiments, the environmental data service 150 maps environmental data to the geographic location of a structural asset using one or more spatial mapping methods. Non-limiting examples of spatial mapping methods include: centroid-based lookup, in which the geographic coordinates of the structural asset's centroid are matched to the nearest weather station or grid point; polygon intersection, in which the footprint polygon of the structural asset is intersected with weather data coverage polygons to identify all overlapping data sources; and inverse-distance weighting, in which environmental data from multiple stations within a configurable radius are combined with weights inversely proportional to their distance from the structural asset. The spatial mapping method may be selected based on the density of available weather stations, the spatial extent of the structural asset, and the desired precision of the environmental data.

### Method Flows

### Forward Prediction Method

Referring to FIG. 3 and FIG. 4, a method for generating a predicted condition representation of a structural asset proceeds as follows.

At step 301, the system receives an initial condition state vector from the image encoder. As described above, the image encoder processes one or more preprocessed historically captured images of the structural asset to produce the initial condition state vector. In embodiments where multiple images are available, the initial condition state vectors may be combined by averaging, attention-weighted aggregation, or temporal interpolation.

At step 302, the system retrieves an environmental event sequence spanning from the capture timestamp to the target time. The environmental data service queries appropriate data sources, constructs event records, and sorts them in chronological order. In some embodiments, event records are aligned to a uniform temporal grid (e.g., daily, weekly, or monthly intervals) by aggregating or interpolating raw data.

At steps 303-306, the system iteratively applies the state-transition function to update the condition state vector. At each iteration i, the system extracts an event feature vector from the i-th environmental event record (step 304), applies the state-transition function to the current condition state vector and the event feature vector to produce an updated condition state vector (step 305), and checks whether all event records have been processed (step 306). In some embodiments, the state-transition function also receives the contextual metadata as an additional input at each step. In some embodiments, the state-transition function produces an explicit state update delta that is added to the current condition state vector, such that the updated condition state vector equals the previous condition state vector plus the state update delta.

At step 307, after all event records have been processed, the system outputs the final updated condition state vector. At step 308, the output derivation module derives one or more condition metrics from the final updated condition state vector. In some embodiments, the system further generates a synthetic image by passing the final updated condition state vector through the generative decoder.

### Divergence Verification Method

Referring to FIG. 7, when a newly acquired image of the structural asset becomes available, the divergence verification module operates as follows.

At step 701, the module receives the synthetic image generated by the generative decoder (or, alternatively, the final updated condition state vector). At step 702, the module receives the newly acquired image. At step 703, the newly acquired image is preprocessed using the same pipeline as the historically captured image. At step 704, the preprocessed newly acquired image is encoded using the image encoder to produce an observed condition state vector.

At step 705, the module computes a divergence measure using one or more metrics. In some embodiments, the divergence measure comprises a weighted combination of embedding-space cosine distance between the predicted and observed condition state vectors, pixel-level structural similarity index between the synthetic and observed images, and a learned perceptual similarity metric. In some embodiments, the divergence measure is a single scalar value; in other embodiments, it is a multi-dimensional vector capturing divergence along different condition attributes.

At step 706, the module compares the divergence measure against a threshold. If the divergence is below the threshold, the system confirms that the predicted condition is consistent with the observation. If the divergence exceeds the threshold, the system proceeds to classify the divergence reason (step 707) and generate an anomaly assessment record (step 708).

In some embodiments, the divergence verification module 180 applies a multi-tier threshold policy to the divergence measure 184. In one non-limiting example, when the divergence measure is computed as a cosine distance between predicted and observed condition state vectors, a first tier (cosine distance less than 0.15) indicates that the prediction is consistent with the observation and no action is required; a second tier (cosine distance between 0.15 and 0.40) triggers a soft flag for the next scheduled review cycle; and a third tier (cosine distance greater than 0.40) triggers an immediate flag for manual review or automated corrective action. In some embodiments, the threshold values are configurable per deployment and may be determined during calibration by analyzing the distribution of divergence measures across a validation dataset. In some embodiments, the threshold values are learned and adapt over time based on feedback data indicating whether flagged divergences corresponded to genuine anomalies.

In some embodiments, the divergence classification at step 707 distinguishes among: (a) suspected repair or replacement, indicated by the observed condition being significantly better than predicted; (b) suspected construction defect, indicated by localized degradation exceeding the rate predicted by environmental exposure alone; (c) suspected missing environmental event data, indicated by widespread degradation exceeding prediction in a manner consistent with a severe weather event; and (d) suspected image artifact or capture-condition difference, indicated by divergence patterns consistent with lighting, angle, or resolution changes rather than physical condition changes.

### ML Lifecycle

### Training Data Generation

Referring to FIG. 8, Stage A, in some embodiments the system generates training data using a synthetic data generation pipeline. The synthetic data generation pipeline produces training tuples comprising initial condition representations, environmental event sequences, and corresponding ground-truth final condition states, using one or more simulation techniques that model the physical effects of environmental stressors on structural materials. The specific architecture, tools, and methodologies used for synthetic data generation are not limiting; any pipeline capable of producing training tuples of the described form is suitable. The training methodology described herein is illustrative and non-limiting; the learned state-transition function may be trained using any suitable training data and methodology, including purely real-world data, purely synthetic data, or any combination thereof.

In some embodiments, the synthetic data generation pipeline produces training tuples comprising an initial condition state or image, an environmental event sequence, and a ground-truth final condition state. The synthetic data generation pipeline may employ any combination of physics-informed degradation models and sequential application of environmental stressor primitives to produce order-dependent degradation trajectories. The details of the synthetic data generation pipeline are non-limiting; alternative approaches to training data generation, including collection of real-world paired observations, semi-supervised learning from partially labeled data, or self-supervised learning from temporal image sequences, may be used.

### Model Training

Referring to FIG. 8, Stage B, in some embodiments the image encoder, state-transition function, environmental event encoder, and output derivation module are trained jointly in an end-to-end pipeline by minimizing a loss function that penalizes discrepancy between the predicted final condition state vector and the ground-truth final condition state. In some embodiments, the loss function comprises a mean squared error or mean absolute error component on the condition state vector dimensions, a condition-metric-specific loss component for each output condition metric, and optionally a regularization term that encourages smoothness of the state-transition function across adjacent time steps. In some embodiments, training uses an adaptive learning rate optimizer and a learning rate schedule such as cosine annealing or step decay.

In some embodiments, the training pipeline processes training sequences of variable length, where each training sequence comprises an initial image, a temporally ordered series of environmental event records, and a ground-truth condition outcome. During training, the image encoder processes the initial image to produce a predicted initial condition state vector, the environmental event encoder transforms each event record into an event feature vector, and the state-transition function iteratively updates the condition state vector through the sequence. The loss is computed between the final predicted condition state vector and the ground-truth condition state. Gradients are backpropagated through the entire sequence, training all components jointly to minimize prediction error. In some embodiments, training-time data augmentation is applied to input images, including noise injection, color jitter, geometric transformations, resolution downsampling and upsampling, and partial occlusion masking, to improve robustness to variable image quality and capture conditions.

In some embodiments, the generative decoder is trained using adversarial training in which a discriminator network evaluates whether a generated image is consistent with the condition state vector from which it was generated. In some embodiments, the generative decoder is trained using a combination of adversarial loss, perceptual loss, and reconstruction loss.

In some embodiments, training is performed in multiple stages: a first stage training the state-transition function on synthetic or large-scale data, and a second stage fine-tuning or calibrating on real-world paired observations. In some embodiments, the second stage uses a smaller learning rate and fewer training iterations to avoid catastrophic forgetting of patterns learned during the first stage. In some embodiments, real-world training data comprises tuples of (a) a historically captured image with a known capture timestamp, (b) an environmental event sequence from the capture time to a later observation time, and (c) a ground-truth condition assessment obtained from a later image, a physical inspection report, an insurance assessment, or a combination thereof. In some embodiments, training and validation data is split using geographic stratification or temporal stratification to ensure the model generalizes across regions and time periods.

In some embodiments, the training dataset comprises between one hundred thousand and fifty million training tuples. In some embodiments, training is performed on computing hardware equipped with one or more accelerators such as GPUs, TPUs, NPUs, or other application-specific integrated circuits, using distributed data-parallel training across multiple devices. Training and inference are not limited to any particular hardware type; any computing hardware capable of executing the described neural network operations is suitable. In some embodiments, the system employs curriculum learning, presenting shorter environmental event sequences early in training and progressively increasing sequence length as the model improves, to stabilize the learning of long-range temporal dependencies.

In some embodiments, the following representative training configuration is used, which is illustrative and non-limiting. The optimizer is AdamW with an initial learning rate of 1e-4 and a weight decay of 1e-2. The learning rate follows a cosine annealing schedule with warm-up over the first 5% of training steps. The batch size is 64 training sequences. Training proceeds for up to 200 epochs with early stopping triggered when the validation mean absolute error on condition metric predictions does not improve for 20 consecutive epochs. Gradient clipping is applied at a maximum gradient norm of 1.0. The loss function is a weighted combination of mean squared error on condition state vector dimensions, mean absolute error on derived condition metrics, and an optional adversarial loss for the generative decoder. These hyperparameters are representative and may be adjusted based on dataset size, computational resources, and model architecture selection.

### Model Monitoring and Drift Detection

Referring to FIG. 11, in some embodiments the system continuously monitors model performance during production operation. Monitoring comprises tracking statistical distributions of input features, condition metric outputs, and confidence indicators, and comparing current distributions against baseline distributions established during validation. In some embodiments, the system computes a drift score for each monitored distribution using statistical distance measures such as Kolmogorov-Smirnov distance or population stability index. When the drift score exceeds a configurable threshold, the system flags the model for retraining or investigation.

In some embodiments, the system maintains a model registry that stores versioned model artifacts including trained weights, training configuration, validation metrics, and deployment metadata. The model registry supports rollback to any previous model version if a newly deployed model exhibits degraded performance.

### Model Architecture and Configuration Options

### Model Architecture Options

The state-transition function may be implemented using any of a plurality of neural network architectures. In some embodiments, the state-transition function comprises a recurrent neural network such as an LSTM or GRU. In some embodiments, the state-transition function comprises a transformer architecture, including transformer encoder, transformer decoder, or transformer encoder-decoder configurations, that processes the full environmental event sequence using self-attention. In some embodiments, the state-transition function comprises a graph neural network operating on a component-graph representation of the structural asset. In some embodiments, the state-transition function comprises a neural ordinary differential equation that models continuous-time state evolution. In some embodiments, the state-transition function comprises a hybrid architecture combining recurrent processing of event sequences with graph-based spatial modeling. The choice of architecture may depend on the structural asset type, the desired temporal resolution, computational budget, and the availability of graph-structured training data.

The image encoder may be implemented using any of: a convolutional neural network (such as ResNet, EfficientNet, DenseNet, or ConvNeXt variants), a vision transformer (such as ViT or DeiT variants), a hybrid convolutional-transformer architecture, or a pre-trained multimodal foundation model. In some embodiments, the image encoder is initialized with weights pre-trained on large-scale image classification or self-supervised learning tasks and fine-tuned for structural condition encoding.

The generative decoder may be implemented using any of: a diffusion model (such as a latent diffusion model or a denoising diffusion probabilistic model), a conditional generative adversarial network, a variational autoencoder decoder, or a ControlNet-augmented diffusion model that accepts condition-state conditioning signals. In some embodiments, the generative decoder comprises a portfolio of specialized sub-decoders, each responsible for rendering a different aspect of structural condition (such as surface texture degradation, crack patterns, color changes, or deformation).

### Environmental Data Source Options

The environmental data service may retrieve data from any of a plurality of sources. In some embodiments, weather data is obtained from national meteorological services. In some embodiments, weather data is obtained from commercial weather data providers. In some embodiments, weather data is obtained from property-mounted weather stations or building management system sensors. In some embodiments, weather data is obtained from radar-derived precipitation and hail databases. In some embodiments, multiple data sources are queried and their data is merged with source-quality-weighted aggregation. The system is agnostic to the specific weather data provider and can integrate new data sources through configurable adapters.

### Output Format Options

Condition metrics may be delivered in any of a plurality of formats. In some embodiments, condition metrics are returned as a JSON, XML, or YAML structured response via a REST API. In some embodiments, condition metrics are exported as rows in a CSV or spreadsheet file. In some embodiments, condition metrics are rendered as a formatted PDF report including synthetic images, charts, and explanatory text. In some embodiments, condition metrics are pushed to external systems via webhooks, message queues, or native integrations with contractor management platforms, building information management systems, insurance underwriting engines, or customer relationship management systems.

### Observability and Enforcement Hooks

In some embodiments, the system generates structured telemetry at each stage of the inference pipeline. The telemetry comprises timing information for each processing stage, input data checksums, intermediate state vector snapshots, output condition metric values, confidence indicators, and any warnings or error conditions encountered. The telemetry is persisted to a logging system and may be used for debugging, performance optimization, audit compliance, and regulatory reporting.

In some embodiments, the system enforces data quality gates at the input stage. If a historically captured image fails quality checks (such as minimum resolution, completeness, or format validity), or if the environmental event sequence has gaps exceeding a configurable maximum, the system may reject the assessment request with an explanatory error, proceed with reduced confidence and an appropriate confidence indicator, or substitute default or interpolated values for missing data.

In some embodiments, the system logs a complete provenance record for each assessment, as described with reference to FIG. 14. The provenance record enables end-to-end traceability from input data through model versions to output metrics, supporting auditing, reproducibility, and regulatory compliance requirements.

In some embodiments, the system generates observable artifacts that provide evidence of the prediction mechanism's execution. These artifacts include: the sequence of state update deltas applied during sequential updating, the final condition state vector and its decomposition into interpretable condition attributes, the synthetic image (if generated), and the divergence measure (if verification was performed). These artifacts enable external verification that the system performed the claimed sequential state-update computation rather than a simpler aggregate scoring computation.

### Operational and Reliability Design

In some embodiments, the system is deployed on a container orchestration platform such as Kubernetes and is configured for horizontal scaling based on request load. Worker nodes process assessment requests in parallel, with a shared environmental data cache reducing redundant data retrieval for geographically proximate properties.

In some embodiments, the system implements a canary deployment strategy for model updates. When a new model version is deployed, a configurable fraction of assessment requests is routed to the new model while the remainder continues to be served by the previous model. If the new model's performance metrics (measured by divergence rates, confidence distributions, or feedback agreement rates) exceed acceptable thresholds, the new model is promoted to serve all traffic. If the new model's performance degrades, the deployment is automatically rolled back.

In some embodiments, the system implements a circuit-breaker pattern for external data service dependencies. If the environmental data service, image source, or other external dependency becomes unavailable or responds with elevated latency, the system degrades gracefully by serving cached data, queuing requests for later processing, or returning partial results with appropriate confidence adjustments.

In some embodiments, the system maintains service level objectives including maximum inference latency per property, maximum batch processing time per portfolio, minimum availability, and maximum error rate. Monitoring infrastructure tracks these metrics and alerts operators when objectives are at risk.

### Edge Cases, Failure Modes, and Mitigations

In some embodiments, when no historically captured image is available for a structural asset, the system initializes the condition state vector from a default prior based on the asset's known age, material type, and geographic region, if such metadata is available. The system proceeds with the sequential state update using this prior-based initialization, with an elevated uncertainty indicator on the resulting assessment.

In some embodiments, when the environmental event sequence contains temporal gaps (such as periods with no available weather data), the system fills the gaps using one or more of: climatological averages for the asset's geographic region and season, interpolation from adjacent available data, or a conservative worst-case assumption that maximizes predicted degradation. In some embodiments, a gap is classified as significant when it spans more than 30 consecutive days, and the system applies a gap-handling policy that selects the fill method based on gap duration: gaps of 30 days or fewer are filled by temporal interpolation from adjacent records; gaps of 31 to 90 days are filled using seasonal climatological averages for the region; and gaps exceeding 90 days trigger a reduced-confidence flag on the resulting assessment record along with climatological fill. The gap-duration thresholds are configurable per deployment. The system annotates the assessment record to indicate the presence, duration, and treatment of any data gaps.

In some embodiments, when a severe environmental event (such as a major hailstorm) is reported in the general vicinity of a structural asset but specific impact on the asset's location is uncertain, the system may produce a probability distribution over possible impact severities rather than a single point estimate. In some embodiments, the system generates multiple condition state vector trajectories corresponding to different impact scenarios and reports the range of outcomes.

In some embodiments, when the system detects that a structural asset has undergone a repair or replacement (either through divergence verification, external data feeds such as building permit databases, or user-provided information), the system handles the state discontinuity by one or more of: reinitializing the condition state vector from a new post-repair image if available, resetting specific dimensions of the condition state vector corresponding to the repaired components while preserving other dimensions, or applying a learned repair-transition function that modifies the condition state vector to reflect the expected effect of the repair type.

In some embodiments, the state-transition function maintains traces of prior condition even after a repair event, such that the condition state vector after a repair is not identical to that of a newly constructed asset. This reflects the physical reality that a re-roofed structure may retain characteristics of its prior condition (such as substrate deterioration or underlying structural stress) that differ from a newly built structure.

In some embodiments, the system implements an abstention mechanism. When the confidence of the predicted condition falls below a configurable threshold, the system declines to produce a definitive assessment and instead returns a notification indicating insufficient confidence along with recommendations for obtaining additional data (such as updated imagery or property inspection).

### Embodiments and Variations

Embodiment 1 (Residential Roof Lead Generation): In one embodiment, the system is configured for residential roofing contractor lead generation. The system processes a batch of residential property addresses, retrieves historically captured aerial or satellite imagery and environmental event sequences for each property, generates condition metrics comprising a damage severity score and an actionable-priority index, and exports the results as a ranked list to an external customer relationship management system.

Embodiment 2 (Commercial Portfolio Monitoring): In one embodiment, the system is configured for commercial building portfolio condition monitoring. A property management organization uploads historical imagery for a portfolio of commercial buildings. The system generates condition assessments for each building's roof and, in some configurations, for facades and pavement surfaces. Results are aggregated into a portfolio dashboard showing condition trends, maintenance prioritization, and capital expenditure forecasting.

Embodiment 3 (Insurance Underwriting Support): In one embodiment, the system generates condition assessments for use by insurance underwriters. The system produces a multi-attribute condition profile comprising damage probability, remaining useful life estimate, and material degradation index. The underwriter uses these metrics to inform pricing, coverage decisions, or claims prioritization.

Embodiment 4 (Homeowner Educational Report): In one embodiment, the system generates a consumer-facing report for a homeowner. The report includes a synthetic image showing the predicted current appearance of the roof, a plain-language condition summary, and suggested maintenance actions. The report is delivered via a web portal or email.

Embodiment 5 (Construction Defect Detection): In one embodiment, the system identifies suspected construction defects by comparing the observed degradation trajectory of a structural asset against a calibration baseline representing expected degradation under the actual environmental conditions experienced. Localized areas where degradation significantly exceeds the calibration baseline are flagged as potential construction defects, enabling targeted inspection and warranty claims.

Embodiment 6 (Bidirectional Temporal Analysis): In one embodiment, the state-transition function supports reverse-temporal application. Given a current image and a target past time, the system applies the state-transition function in reverse, using the environmental event sequence in reverse chronological order, to estimate the condition of the structural asset at the earlier time. This enables forensic analysis of when specific degradation events likely occurred and supports claims investigation and warranty assessment.

Embodiment 7 (Counterfactual Scenario Modeling): In one embodiment, the system supports counterfactual analysis by modifying the environmental event sequence to simulate hypothetical scenarios. For example, a user may specify a hypothetical severe hailstorm at a particular date and the system predicts the resulting condition trajectory. Alternatively, a user may specify a hypothetical repair at a particular date and the system predicts the resulting improvement in remaining useful life.

Embodiment 8 (Multi-Modal Input): In one embodiment, the system accepts additional input modalities beyond optical imagery and weather data. Additional modalities may include thermal imagery, LiDAR point cloud data, hyperspectral imagery, building permit records, property inspection reports, maintenance logs, or building management system sensor data. Each additional modality is processed by a modality-specific encoder that produces a fixed-dimensional representation, which is combined with the image-derived condition state vector and the environmental event data in the state-transition function.

Embodiment 9 (Spatially Resolved Condition Mapping): In one embodiment, the system produces a spatially resolved condition map rather than a single condition state vector for the entire structural asset. The structural asset is partitioned into a grid of spatial regions, each associated with its own condition state sub-vector. The state-transition function updates each sub-vector while modeling interactions between adjacent regions through message-passing or attention mechanisms. The output is a spatial condition map indicating localized degradation patterns.

Embodiment 10 (Material-Conditioned Prediction): In one embodiment, the state-transition function is explicitly conditioned on the material type of the structural asset. Material type may be provided as known metadata, inferred from the historically captured image by a material classification sub-module, or represented as a probability distribution over candidate materials. The state-transition function modulates its degradation modeling based on the material type, reflecting the different degradation characteristics of different materials under the same environmental exposure.

Embodiment 11 (Multi-Image Initialization): In one embodiment, when multiple historically captured images of the same structural asset are available from different times, the system initializes multiple condition state vectors and processes each through its respective environmental event sequence to the same target time. The system then reconciles the multiple resulting condition state vectors by averaging, weighted combination based on input image quality, or attention-based aggregation. This multi-image approach increases robustness and may reduce prediction uncertainty.

Embodiment 12 (Edge Deployment with Distilled Models): In one embodiment, compressed or distilled versions of the image encoder, the state-transition function, and optionally the output derivation module are deployed on an edge device such as a tablet or laptop for field use. The edge-deployed models perform single-property assessments with reduced latency and without requiring network connectivity to a cloud service. In some embodiments, the distilled models are produced using knowledge distillation from larger teacher models, followed by quantization to reduced numerical precision, architectural pruning, or both. In some embodiments, the entire inference pipeline from image encoding through sequential state updating to condition metric derivation executes locally on the edge device using the distilled model components. In some embodiments, the edge device executes inference on any of a CPU, GPU, NPU, or other application-specific accelerator.

Embodiment 13 (Streaming Event Processing): In one embodiment, the system processes environmental event records in a streaming fashion as they become available, maintaining a persistent condition state vector for each monitored structural asset. Each new event record triggers an incremental state update. This enables continuous real-time condition monitoring rather than batch-mode periodic assessment.

Embodiment 14 (Intervention Signal Injection): In one embodiment, the environmental event sequence includes intervention events representing human actions such as roof coatings, sealant applications, partial repairs, or protective cover installations. Each intervention event is encoded as a special event feature vector that the state-transition function processes to update the condition state vector in a manner reflecting the expected restorative or protective effect of the intervention.

Embodiment 15 (Out-of-Order Event Handling): In one embodiment, when environmental event records arrive out of chronological order (such as when historical data is updated retroactively), the system reprocesses the condition state vector from the earliest affected time step using the corrected event sequence. In some embodiments, the system maintains checkpointed condition state vectors at periodic intervals to enable efficient reprocessing without re-running from the initial state.

Embodiment 16 (Uncertainty-Aware State Updates): In one embodiment, the state-transition function produces not only an updated condition state vector but also an uncertainty estimate for each dimension of the vector. The uncertainty estimate grows with each state update reflecting the accumulating prediction uncertainty over longer temporal horizons. Downstream condition metrics incorporate the uncertainty estimate, enabling the system to communicate the reliability of its predictions.

Embodiment 17 (Non-Roof Structural Assets): In one embodiment, the system is configured for structural assets other than roofs, including building facades, siding, gutters, pavements, bridge decks, retaining walls, or pool enclosures. The system uses asset-type-specific image encoders and condition metric definitions while sharing the core sequential state-update architecture. In some embodiments, a single cross-domain state-transition function is trained on diverse asset types, learning shared degradation principles that transfer across asset categories.

Embodiment 18 (Multi-Tenant Architecture): In one embodiment, the system operates in a multi-tenant configuration where multiple organizations share the same deployed infrastructure while maintaining isolated data stores, access controls, and optionally customized model configurations. Each tenant's assessment requests, imagery, and results are stored in tenant-specific partitions. In some embodiments, tenant-specific model fine-tuning is supported, enabling each tenant to calibrate the system to their specific geographic region or asset portfolio.

Embodiment 19 (Assessment Record Provenance and Auditability): In one embodiment, each assessment record includes a complete provenance chain as described with reference to FIG. 14, enabling end-to-end traceability from input data through model versions to output metrics. In some embodiments, assessment records are stored in an append-only data store that prevents retroactive modification, supporting regulatory compliance and dispute resolution.

Embodiment 20 (Integrated Synthetic Data and Real-World Calibration): In one embodiment, the training pipeline comprises a first stage using synthetic training data generated by a construction grammar and simulation engine as described with reference to FIG. 8, followed by a second stage fine-tuning on real-world paired observations. This two-stage approach enables the state-transition function to learn robust degradation patterns from large-scale synthetic data and then calibrate to real-world conditions using limited but high-fidelity field data.

Embodiment 21 (Material Manufacturer Virtual Laboratory): In one embodiment, the system is configured as a virtual testing laboratory for structural material manufacturers. A manufacturer provides material property specifications for a candidate roofing material, and the system initializes a condition state vector representing a pristine installation of the candidate material. The system then applies accelerated environmental event sequences representing years or decades of exposure to standardized or geographically specific environmental profiles. The resulting condition state trajectories, condition metrics, and optional synthetic images enable the manufacturer to evaluate material durability, compare candidate formulations, optimize material properties, and generate certification data without conducting physical weathering tests that would require months or years of real-time exposure. In some embodiments, the manufacturer compares multiple material formulations by running parallel condition trajectories under identical environmental event sequences and ranking the formulations by predicted remaining useful life, damage resistance, or maintenance interval.

### Concrete Examples

Example 1 (Residential Roof—Hail and UV Exposure): A residential property in a central United States location has a historically captured aerial image from 18 months prior. The system embeds the image into a 128-dimensional condition state vector. The environmental event sequence comprises 18 months of daily event records. Notable events include a severe hailstorm with 38-millimeter diameter hail at month 6, sustained high UV index periods during the summer months, and multiple freeze-thaw cycles during the winter. The state-transition function processes each event in sequence, producing state update deltas that reflect increasing granule loss from hail, accelerating UV embrittlement, and thermal fatigue accumulation. The final condition state vector is decoded into a damage severity score of 72 on a 0 -100 scale, a remaining useful life estimate of 4.2 years, and a synthetic image showing granule loss patterns and minor cracking consistent with the predicted degradation. An actionable-priority index of 85 on a 0 -100 scale is derived, indicating elevated maintenance need.

Example 2 (Commercial Flat Roof—Membrane Degradation): A commercial warehouse has a drone-captured image from 24 months prior showing a thermoplastic polyolefin membrane roof. The environmental event sequence includes sustained high temperatures, UV exposure, and several wind events. The state-transition function, conditioned on the known membrane material type, models UV stabilizer depletion, seam stress from thermal expansion, and wind uplift effects. The final condition state vector yields a predicted membrane integrity score of 58 and a seam condition score of 43, flagging the property for proactive maintenance.

Example 3 (Divergence Detection—Unreported Repair): The system generates a predicted condition for a residential property and produces a synthetic image showing significant granule loss and minor cracking. When a newly acquired satellite image becomes available, the divergence verification module computes a cosine distance of 0.62 between the predicted condition state vector and the observed condition state vector derived from the newly acquired image, exceeding the 0.40 immediate-flag threshold. The divergence classification at step 707 identifies a suspected repair or replacement because the observed condition is significantly better than predicted across all damage-related dimensions. The assessment record is annotated with the divergence finding, the cosine distance value, and the classification, and the condition state vector is reinitialized from the new imagery for subsequent assessments.

Example 4 (Construction Defect Identification): The system monitors a neighborhood of 40 newly constructed homes. After 18 months, the system generates predicted conditions for each property using identical environmental event sequences (the homes are in close geographic proximity and experienced the same weather). Most properties yield divergence measures below 0.15 (cosine distance between predicted and observed condition state vectors), confirming consistency with the calibration baseline. Three properties yield divergence measures of 0.51, 0.47, and 0.44 respectively, each exceeding the 0.40 immediate-flag threshold. The elevated divergence is concentrated in valley and flashing sub-regions of the spatially resolved condition map, where observed degradation exceeds the rate predicted by environmental exposure alone by a factor of 2.3 to 3.1 in damage-severity dimensions. The system flags these properties as potential construction defects, producing divergence assessment records with spatial condition maps highlighting the affected regions, the per-region divergence values, and the anomaly classification.

Example 5 (Counterfactual Analysis—Coating Application): A property manager evaluates the return on investment of applying a protective roof coating. The system runs two condition trajectories from the current state: one with the standard environmental event sequence, and one with an intervention event representing the coating application inserted at the current time followed by the same environmental sequence with modified material response parameters. The system reports that the coating extends the predicted remaining useful life by 3.8 years, providing a quantitative basis for the investment decision.

Example 6 (Batch Portfolio Assessment): An insurance company submits a portfolio of 50,000 residential properties for assessment. The batch processing architecture distributes the assessments across worker nodes, leveraging the shared environmental data cache for geographic clustering. The system produces assessment records for all properties within the agreed processing time, along with a portfolio summary comprising aggregate condition distribution, a geographic heat map of predicted damage severity, and a ranked list of highest-risk properties.

Example 7 (Reverse-Temporal Forensic Analysis): Following a property damage claim, an insurance investigator uses the system to estimate the condition of the roof at a date six months prior to the claimed damage event. The system applies the state-transition function in reverse from a current image, computing the condition state vector at the earlier date. The investigator compares this estimated historical condition against the claimant's representations to assess claim validity.

Example 8 (Edge Deployment for Field Inspectors): A roofing contractor deploys a tablet application containing a distilled version of the state-transition function. During site visits, the contractor photographs the roof and the application immediately generates a condition assessment using locally stored environmental data. The assessment guides the contractor's inspection focus and is uploaded to the cloud system when connectivity is restored.

Example 9 (Multi-Modal Assessment with Thermal Data): In an embodiment incorporating thermal imagery, the system processes both a visible-light aerial image and a thermal image of a commercial building roof. The visible-light image encoder produces a visual condition state vector, and a thermal image encoder produces a thermal condition state vector. The two vectors are combined and processed through the state-transition function. The thermal data enables detection of moisture infiltration that is invisible in optical imagery, improving the accuracy of the condition assessment.

### Advantages and Technical Improvements

The disclosed system provides a technical improvement in computational efficiency for structural asset condition assessment by enabling condition estimation from existing imagery without requiring the logistical overhead and cost of new image capture. A single historically captured image, combined with readily available environmental data, is computationally transformed into a predicted current or future condition representation.

The sequential, event-conditioned state-update mechanism provides a technical improvement over aggregate scoring approaches by modeling the order-dependent and interactive nature of environmental degradation. Because the state-transition function processes events sequentially and the condition state vector retains information about prior degradation history, the system captures nonlinear interactions (such as UV embrittlement followed by hail impact producing greater damage than the reverse order) that aggregate approaches inherently cannot represent.

The high-dimensional condition state vector provides a technical improvement in information richness over scalar scoring. A single condition state vector supports derivation of diverse condition metrics for different downstream applications, eliminating the need to run separate assessment pipelines for different use cases.

The divergence verification mechanism provides a technical improvement in condition assessment reliability by creating a closed-loop validation capability. When newly acquired imagery becomes available, the system can quantitatively assess the accuracy of its prediction and detect anomalous conditions that warrant further investigation.

The feedback and retraining loop provides a technical improvement in assessment accuracy over time by incorporating real-world field verification data into the model's training process. This creates a virtuous cycle in which deployed use generates calibration data that improves future predictions.

The synthetic data generation pipeline provides a technical improvement in training efficiency by enabling generation of large-scale, diverse training data without requiring prohibitively expensive real-world data collection. The construction grammar and simulation engine produce physically plausible degradation trajectories that the state-transition function can learn from, while real-world calibration corrects for simulation-to-reality gaps.

### Interpretation and Non-Limiting Examples

The foregoing detailed description is to be understood as being in every respect illustrative and exemplary, but not restrictive, and the scope of the invention disclosed herein is not to be determined from the detailed description, but rather from the claims as interpreted according to the full breadth permitted by the patent laws. It is to be understood that the embodiments shown and described herein are only illustrative of the principles of the present invention and that various modifications may be implemented by those skilled in the art without departing from the scope and spirit of the invention. Those skilled in the art could implement various other feature combinations without departing from the scope and spirit of the invention. It will be appreciated by those skilled in the art that the block diagrams illustrated herein represent conceptual views of illustrative functions, operations, and circuitry of the principles described in the various embodiments herein. Similarly, it will be appreciated that any flowcharts, flow diagrams, state transition diagrams, and the like represent various processes that may be substantially represented in computer-readable medium and so executed by a computer, machine, or processor, whether or not such computer, machine, or processor is explicitly shown. The various embodiments described herein can be embodied in the form of methods, systems, and computer program products for practicing those methods. The disclosed methods may be performed by a combination of hardware, software, firmware, middleware, and computer-readable media installed in and communicatively connected to a user device or a server, as described herein.

What is claimed is:

1. A computer-implemented method for generating a predicted condition representation of a structural asset from historically captured imagery, the method comprising:
receiving, by at least one processor, at least one historically captured image of a structural asset, each image associated with a respective capture timestamp;
generating, by the at least one processor, an initial condition state vector by processing the at least one historically captured image through an image encoder neural network, wherein the initial condition state vector is a multi-dimensional numerical representation encoding visual and structural characteristics of the structural asset as of the capture timestamp;
retrieving an environmental event sequence comprising a plurality of time-ordered environmental event records spanning from the capture timestamp to a target time, wherein each environmental event record characterizes at least one environmental condition affecting the structural asset during a corresponding time interval;
iteratively updating, by the at least one processor, the condition state vector by applying a learned state-transition function to the condition state vector and each successive environmental event record in the environmental event sequence to produce an updated condition state vector, wherein the learned state-transition function has been trained to model changes in structural asset condition responsive to environmental conditions; and
deriving at least one condition metric from the updated condition state vector, wherein the at least one condition metric indicates a predicted condition of the structural asset at the target time.

2. The method of claim 1, further comprising, prior to generating the initial condition state vector, performing at least one of super resolution upscaling, denoising, style normalization, or geometric correction on the at least one historically captured image.

3. The method of claim 1, wherein the environmental event records comprise at least one of: hail occurrence and hail diameter, wind speed and wind direction, precipitation amount and precipitation type, temperature range, ultraviolet radiation index, freeze-thaw cycle count, or humidity.

4. The method of claim 1, wherein iteratively updating the condition state vector comprises, at each iteration, computing a state update delta and additively applying the state update delta to the condition state vector to produce the updated condition state vector.

5. The method of claim 1, wherein the at least one condition metric comprises a plurality of condition attributes including at least two of: a damage severity score, a material degradation index, a remaining useful life estimate, or a maintenance urgency indicator.

6. The method of claim 1, further comprising decoding the updated condition state vector into a synthetic image of the structural asset using a generative decoder neural network, wherein the synthetic image approximates a visual appearance of the structural asset at the predicted condition.

7. The method of claim 6, further comprising:
receiving a newly acquired image of the structural asset captured at or near the target time;
computing a divergence measure between the synthetic image and the newly acquired image; and
responsive to the divergence measure exceeding a threshold, generating an anomaly assessment record.

8. The method of claim 7, wherein generating the anomaly assessment record comprises classifying a reason for the divergence measure as at least one of: a suspected repair or replacement, a suspected construction defect, a suspected environmental event not captured in the environmental event sequence, or a suspected image artifact.

9. The method of claim 1, wherein the learned state-transition function is further conditioned on contextual metadata comprising at least one of: a material type of the structural asset, a structural geometry parameter, or a geographic region identifier.

10. The method of claim 1, wherein the learned state-transition function models cross-stressor interaction effects such that an effect of a second environmental stressor on the condition state vector depends on a current state of the condition state vector as modified by prior application of the learned state-transition function in response to one or more earlier environmental event records in the environmental event sequence.

11. A system for predictive condition assessment of structural assets, the system comprising:
at least one processor; and
a memory storing instructions that, when executed by the at least one processor, cause the system to perform operations comprising:
receiving at least one historically captured image of a structural asset, each image associated with a respective capture timestamp;
generating an initial condition state vector by processing the at least one historically captured image through an image encoder neural network, wherein the initial condition state vector is a multi-dimensional numerical representation encoding visual and structural characteristics of the structural asset as of the capture timestamp;
retrieving an environmental event sequence comprising a plurality of time-ordered environmental event records spanning from the capture timestamp to a target time, wherein each environmental event record characterizes at least one environmental condition affecting the structural asset during a corresponding time interval;
iteratively updating the condition state vector by applying a learned state-transition function to the condition state vector and each successive environmental event record in the environmental event sequence to produce an updated condition state vector, wherein the learned state-transition function has been trained to model changes in structural asset condition responsive to environmental conditions; and
deriving at least one condition metric from the updated condition state vector, wherein the at least one condition metric indicates a predicted condition of the structural asset at the target time.

12. The system of claim 11, wherein the operations further comprise decoding the updated condition state vector into a synthetic image of the structural asset using a generative decoder neural network.

13. The system of claim 11, wherein the operations further comprise:
receiving a newly acquired image of the structural asset;
computing a divergence measure between a predicted condition representation and the newly acquired image; and
responsive to the divergence measure exceeding a threshold, generating an anomaly assessment record.

14. The system of claim 11, wherein the operations further comprise transforming each environmental event record into an event feature vector by processing the environmental event record through an environmental event encoder neural network prior to applying the learned state-transition function, wherein the environmental event encoder neural network projects heterogeneous environmental data fields into a fixed-dimensional numerical representation.

15. The system of claim 11, wherein the learned state-transition function models cross-stressor interaction effects such that an effect of a second environmental stressor on the condition state vector depends on a current state of the condition state vector as modified by prior application of the learned state-transition function in response to one or more earlier environmental event records in the environmental event sequence.

16. A non-transitory computer-readable medium storing instructions that, when executed by one or more processors, cause the one or more processors to perform operations comprising:
receiving at least one historically captured image of a structural asset, each image associated with a respective capture timestamp;
generating an initial condition state vector by processing the at least one historically captured image through an image encoder neural network, wherein the initial condition state vector is a multi-dimensional numerical representation encoding visual and structural characteristics of the structural asset as of the capture timestamp;
retrieving an environmental event sequence comprising a plurality of time-ordered environmental event records spanning from the capture timestamp to a target time, wherein each environmental event record characterizes at least one environmental condition affecting the structural asset during a corresponding time interval;
iteratively updating the condition state vector by applying a learned state-transition function to the condition state vector and each successive environmental event record in the environmental event sequence to produce an updated condition state vector, wherein the learned state-transition function has been trained to model changes in structural asset condition responsive to environmental conditions; and
deriving at least one condition metric from the updated condition state vector, wherein the at least one condition metric indicates a predicted condition of the structural asset at the target time.

17. The non-transitory computer-readable medium of claim 16, wherein the operations further comprise decoding the updated condition state vector into a synthetic image of the structural asset using a generative decoder neural network.

18. The non-transitory computer-readable medium of claim 16, wherein the operations further comprise:
receiving a newly acquired image of the structural asset;
computing a divergence measure between a predicted condition representation and the newly acquired image; and
responsive to the divergence measure exceeding a threshold, classifying a reason for the divergence measure to produce a classification, and generating an anomaly assessment record comprising the classification.

19. The non-transitory computer-readable medium of claim 16, wherein the learned state-transition function models cross-stressor interaction effects such that an effect of a second environmental stressor on the condition state vector depends on a current state of the condition state vector as modified by prior application of the learned state-transition function in response to one or more earlier environmental event records in the environmental event sequence.

20. The non-transitory computer-readable medium of claim 16, wherein the operations further comprise generating and persisting a log of state update deltas applied at each iteration of the iteratively updating step, the log enabling audit and replay of the sequential condition-update computation
